(19) United States
(12) Patent Application Publication
(10) Pub. No.: US 2010/0072629 A1
(43) Pub. Date: Mar. 25, 2010

(54) Wiring Structure, Semiconductor Device Having the Wiring Structure, and Method for Manufacturing the Semiconductor Device

(76) Inventor: Min Hyung LEE, Cheongju-si (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/562,019

(22) Filed: Sep. 17, 2009

(30) Foreign Application Priority Data
Sep. 22, 2008 (KR) 10-2008-0092707

(51) Int. Cl. H01L 23/48; H05K 1/00; H01L 21/768

(52) U.S. Cl. 257/774; 174/262; 438/675; 257/E23.011; 257/E21.577

(57) ABSTRACT

A wiring structure, a semiconductor device having the structure, and a method for manufacturing the semiconductor device are disclosed. The wiring structure includes a first metal layer, a second metal layer on the first metal layer, an insulating layer between the first metal layer and the second metal layer, and a metal via pattern formed in the insulating layer to electrically connect the first and second metal layers to each other. The metal via pattern includes a plurality of metal vias spaced apart from one another, and each of the metal vias includes a vertical via line extending in a vertical direction and a horizontal via line extending in a horizontal direction to cross the vertical via line. The wiring structure may achieve minimized chip defects, fewer cracks in the insulating layer, effective use of the occupation area of a semiconductor chip, and reduced chip size and manufacturing costs.

This application claims the benefit of Korean Patent Application No. 10-2008-0092707, filed on 22 Sep. 2008, which is hereby incorporated by reference as if fully set forth herein.

### BACKGROUND OF THE INVENTION

1. Field of the Invention

The present invention relates to all products using wire bonding, and more particularly, to a wiring structure of a semiconductor chip, a semiconductor device having the wiring structure, and a method for manufacturing the semiconductor device.

2. Discussion of the Related Art

Wire bonds, which are electrically or physically connected to underlying circuits of semiconductor chips, are used to connect the specific semiconductor chips to packaging elements, such as Printed Circuit Boards (PCBs) or ceramic modules.

Bonding pads correspond to an interface between chip packages and integrated circuits included in semiconductor chips. To transmit power, connect to a ground plane, or carry input/output signals to and from chip devices, there is a need for a great number of bonding pads. Wires are bonded to bonding pads and chip packages, thus electrically connecting chips and packages to each other. With recent developments in semiconductor integration technology, the relative proportion of the area of bonding pads in a chip is gradually increasing. However, in the case of semiconductor chips using a wire bonding type package as described above, if transistors are present below the bonding pads, the transistors may be damaged or broken by stress due to the bonding force used during wire bonding. For this reason, it may be important not to provide transistors below a region where bonding pads are arranged. Accordingly, the occupation region of bonding pads may problematically reduce the number of chips on a per wafer basis.

### SUMMARY OF THE INVENTION

Accordingly, the present invention is directed to a wiring structure, a semiconductor device having the wiring structure, and a method for manufacturing the semiconductor device that substantially obviate one or more problems due to limitations and disadvantages of the related art.

An object of the present invention is to provide a wiring structure, a semiconductor device having the wiring structure, and a method for manufacturing the semiconductor device, wherein a metal via pattern is formed below a bonding pad (where the bonding pad may serve as an uppermost metal layer of the semiconductor device) and serves to reduce, more evenly distribute or endure stress applied to the integrated circuit during wire bonding, thereby allowing an integrated circuit to be placed or arranged even below the bonding pad.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

To achieve these objects and other advantages and in accordance with the purpose of the invention, as embodied and broadly described herein, a wiring structure may include a first metal layer, an insulating layer on the first metal layer, a metal via pattern in the insulating layer, electrically connected to the first metal layer, wherein the metal via pattern includes a plurality of metal vias spaced apart from one another, and each of the metal vias includes a vertical via line extending in a vertical direction and a horizontal via line extending in a horizontal direction crossing the vertical via line, and a second metal layer on the insulating layer and the metal via pattern.

In accordance with another aspect of the invention, a semiconductor device may include an integrated circuit substrate, a first metal layer on the integrated circuit substrate, an insulating layer on the first metal layer, a metal via pattern in the insulating layer, electrically connected to the first metal layer, wherein the metal via pattern includes a plurality of metal vias spaced apart from one another, and each of the metal vias includes a vertical via line extending in a vertical direction and a horizontal via line extending in a horizontal direction crossing the vertical via line, and a second metal layer on the insulating layer and the metal via pattern.

In accordance with a further aspect of the invention, a method for manufacturing a semiconductor device may include preparing an integrated circuit substrate, forming a first metal layer on the integrated circuit substrate, forming an insulating layer on the first metal layer, and forming a metal via pattern in the insulating layer, the metal via pattern being electrically connected to the first metal layer, wherein the metal via pattern includes a plurality of metal vias spaced apart from one another, and each of the metal vias includes a vertical via line extending in a vertical direction and a horizontal via line extending in a horizontal direction crossing the vertical via line.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIG. 1 is a plan view illustrating an exemplary wiring structure according to the present invention;

FIG. 2 is a cross-sectional view taken along the line I-I′ of FIG. 1; and

FIG. 3 is a view illustrating exemplary numerical values related to metal vias of a metal via pattern shown in FIG. 1.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, an exemplary wiring structure and a semiconductor device having the exemplary wiring structure according to an embodiment of the present invention will be described with reference to the accompanying drawings.

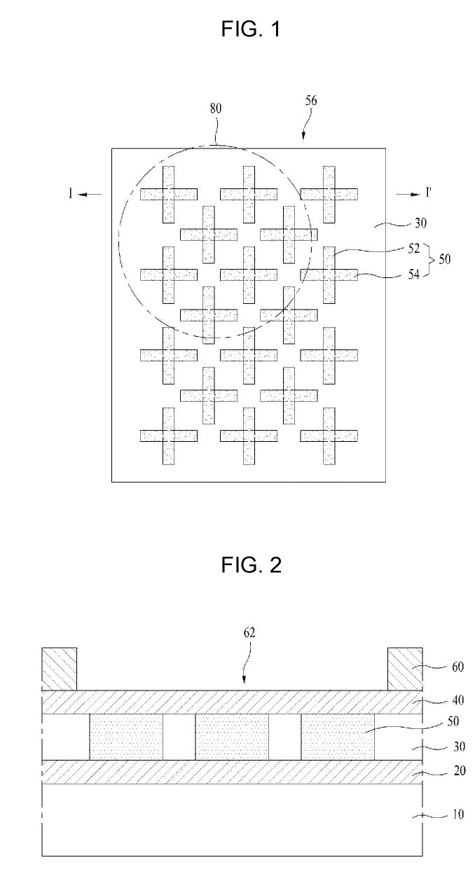

FIG. 1 is a plan or layout view illustrating an exemplary wiring structure according to the present invention, and FIG. 2 is a cross-sectional view taken along the line I-I′ of FIG. 1.

Referring to FIGS. 1 and 2, the wiring structure according to the present invention includes a first metal layer 20, an insulating layer 30, a second metal layer 40, and a metal via pattern 56. In addition, the semiconductor device having the above-described wiring structure may further include an integrated circuit substrate 10 and a passivation layer 60.

First, the first metal layer 20 is formed on the integrated circuit substrate 10. The integrated circuit substrate 10 includes a semiconductor substrate, which may comprise bulk silicon (e.g., amorphous silicon, polysilicon and/or epitaxial silicon), a semiconductor wafer (e.g., a single-crystal silicon wafer), a silicon-on-insulator (SOI) substrate, or a substrate containing SiGe, Ge, GaAs, GaP, InAs, or InP. The integrated circuit substrate 10 may further include integrated circuit structures (as described herein) and one or more layers of metal wiring, covered by an insulating layer (e.g., an interlayer dielectric), which may be planarized (e.g., by chemical mechanical polishing) prior to forming the first metal layer 20 thereon.

The second metal layer 40 is formed above the first metal layer 20.

In Back-End-Of-Line (BEOL) interconnection technology, the second metal layer 40 is an uppermost metal layer, which is manufactured as a top interconnection level metal layer. The second bonding layer 40 corresponds to a bonding pad. Also, the first metal layer 20 corresponds to a second to last level metal layer formed before the uppermost metal layer 40.

The insulating layer 30 is formed on the first metal layer 20, before the second metal layer 40. For example, the insulating layer 30 may comprise one or more films of SiO₂, (which may be formed from a precursor such as tetraethyl orthosilicate [TEOS] or silane), SiNₓ, SiON, a phosphosilicate glass (PSG), a borophosphosilicate glass (BPSG), SiO₂ containing Fe, or any one of various types of low-k films having a relatively low dielectric constant, such as a fluorosilicate glass (FSG) or a silicon oxycarbide (SiOC, which may be hydrogenated [SiOCH]).

The metal via pattern 56 is formed in the insulating layer 30 and serves to electrically connect the first metal layer 20 and second metal layer 40 to each other. The metal via pattern 56 includes a plurality of metal vias 50 spaced apart from one another. Each of the metal vias 50 includes a vertical via line 52 and a horizontal via line 54. The vertical via line 52 extends in a vertical direction, and the horizontal via line 54 extends in a horizontal direction across the vertical via line 52. While a “crossover” region is shown by a square at the intersection of the vertical via line 52 and the horizontal via line 54, in general, it is not a distinct structure, as the metal via 50 is generally a unitary structure. In other words, the metal via 50 can be considered to have a substantially square (or rectangular) portion in the center, and substantially rectangular portions extending therefrom. While 4 such rectangular portions are shown, the metal via 50 may have more (e.g., 6 or 8) or less (e.g., 3) such rectangular portions, and the rectangular portions shown may have any of a variety of shapes (e.g., square, hemispherical, semi-oval, a combination of square or rectangular with hemispherical or semi-oval as the end away from the central square or rectangle, etc.). However, “X” shaped vias may offer particular advantages in ease of mask-making, photolithographic reproduction, and/or distribution of stress or pressure during wire bonding, although other shapes (e.g., “T” shapes, “H” shapes, “E” shapes, “window frame” type shapes, etc.) may also be suitable.

In the case where the metal via pattern 56 is formed in the insulating layer 30 between the first metal layer 20 and the second metal layer 40 as described above, it may be possible to prevent the insulating layer 30 from cracking during wire bonding due to the stress applied to an exposed surface of the second metal layer 40 that serves as a bonding pad. For example, the metal via pattern 56 may absorb or more evenly distribute the stress over the area of the via pattern 56. Provision of the metal via pattern 56 allows an integrated circuit to be formed below the wiring structure. Thus, although not shown in FIGS. 1 and 2, an integrated circuit can be formed in or over the integrated circuit substrate 10. Here, the integrated circuit may denote an electronic circuit having a plurality of individual circuit elements, such as transistors, diodes, resistors, capacitors, inductors, active semiconductor devices, or passive semiconductor devices. The integrated circuit may further include one or more metal wiring layers similar to that disclosed herein for the first metal layer 20 and a corresponding number of interlayer dielectrics to insulate between the underlying metal layers and between the uppermost underlying metal layer and the first metal layer 20.

In the above-described semiconductor device, the metal via pattern 56 may have various sizes and shapes in consideration of the performance of the semiconductor device, mechanical strength, via density, and the like, as long as a vertical via line (e.g., the vertical via line 52) and a horizontal via line (e.g., horizontal via line 54) of the metal via pattern 56 cross each other. Hereinafter, the shapes of the metal via pattern 56 according to embodiments of the present invention will be described with reference to the accompanying drawings.

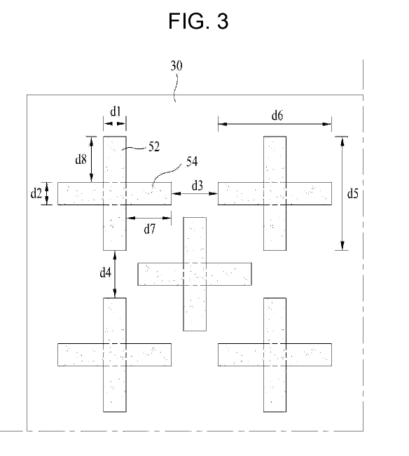

FIG. 3 is a view illustrating exemplary numerical values relating to the metal vias 50 of the metal via pattern 56 shown in FIG. 1, in which part of the circular portion 80 shown in FIG. 1 is illustrated in enlarged scale.

Referring to FIG. 3, a width d1 of the vertical via line 52 and a width d2 of the horizontal via line 54 may be equal to each other. For example, the width d1 and/or d2 may be in a range of 0.1 μm to 50 μm. Although not shown, the thicknesses of the vertical via line 52 and the horizontal via line 54 are generally equal to each other.

Also, a length d5 of the vertical via line 52 and a length d6 of the horizontal via line 54 may be equal to each other. For example, the length d5 and/or d6 may be in a range of 0.3 μm to 250 μm. In this case, a side length d7 of the horizontal via line 54 and a side or extension length d8 of part of the vertical via line 52 may be equal to each other, as well as the corresponding extensions of the vertical via line 52 and/or the horizontal via line 54 on the other side of the central square of the via 50. The side or extension length d7 or d8 may be in a range of 0.1 μm to 100 μm.

Further, a horizontal distance d3 and a vertical distance d4 between adjacent metal vias 50 in a horizontal or vertical direction may be equal to each other. The horizontal or vertical distance d3 or d4 may be 1.1 to 3 times the width d1 or d2.

Of the possible total area of the insulating layer 30 shown in FIG. 1 (e.g., equal to the total area of the second metal layer 40 in the bond pad), the percentage of the area occupied by the metal via pattern 56 may be in a range of 1% to 80% (e.g., 10% to 60%, 20% to 50%, or any other range therein).

It is noted that, although FIG. 3 illustrates the vertical via line 52 and horizontal via line 54 crossing each other at a right angle, the present invention is not limited thereto, and the vertical via line 52 and horizontal via line 54 may cross each other at an angle larger or smaller than a right angle.

In the above description, all the metal vias 50 shown in FIG. 3 have the same shape and are spaced apart from one another by the same distance. However, the present invention is not limited thereto, and the metal vias 50 may have various shapes and sizes and spacings apart from one another by different distances as long as the vertical via line 52 and horizontal via line 54 of each metal via 50 cross each other. In addition, the above mentioned numerical values may vary appropriately based on a given set of design rule values.

The passivation layer 60 shown in FIG. 2 defines a pad window 62. The pad window 62 may be a bonding area, a probing area, or a combination thereof. That is, the pad window 62 denotes an exposed surface of the second metal layer 40 for electric connection of a metal pad and a bonding wire.

Hereinafter, a method for manufacturing the semiconductor device having a wiring structure according to one or more of the embodiments of the present invention will be described with reference to FIG. 2.

First, the integrated circuit substrate 10 is prepared in accordance with conventional integrated circuit manufacturing techniques.

Next, the first metal layer 20 is formed on the integrated circuit substrate 10, generally by sputtering and/or chemical vapor deposition. The first metal layer 20 may comprise a metal such as Cu, Al or an Al alloy (e.g., AlCu, which may contain 0.5-4.0 wt. % Cu, AlTi which may contain up to 25 at. % Ti, or AlTiSi which may contain up to 2 wt. % Ti and up to 1 wt. % Si). Materials such as Al or an Al alloy may be deposited by sputtering onto thin underlying layers of an adhesive conductor, such as Ti or Ta, and an optional barrier layer thereon, such as TiN, TaN, HfN, TiSiN or TaSiN, whereas Cu is generally deposited by electroplating onto an adhesive conductor, a barrier layer thereon, and a nucleation layer on the barrier layer, as described herein. In the case of Al or Al alloy, a thin layer of an adhesive conductor such as Ti may be sputtered thereon, and a hillock suppression and/or anti-reflective coating layer such as TiN or TiW alloy is deposited on the upper adhesive layer, generally by sputtering.

Next, the insulating layer 30 is formed on the first metal layer 20. For example, the insulating layer 30 may be formed on the first metal layer 20 by various deposition methods, such as, e.g., spin coating or chemical vapor deposition (CVD).

Next, the metal via pattern 56 is formed in the insulating layer 30. For example, a plurality of openings are formed in the insulating layer 30 at positions corresponding to the metal vias 50 by photolithography and etching processes. An anisotropic etching process, such as plasma etching or reactive ion etching, may be used to expose the first metal layer 20. Thereafter, a conductive material is deposited (e.g., gap-filled) in the openings. Here, the conductive material may be deposited by a well-known plug formation process, such as, e.g., a tungsten plug process, an aluminum plug process, a copper plug process, or a silicide plug process. Such plug processes may also be considered “single damascene” processes in the art. Thereafter, the conductive material may be polished by a chemical mechanical polishing (CMP) process until the insulating layer 30 is exposed.

Here, the plurality of metal vias 50 may be spaced apart from one another, to define the metal via pattern 56. Each of the metal vias 50 includes the vertical via line 52 extending in a vertical direction and the horizontal via line 54 extending in a horizontal direction across the vertical via line 52.

Each metal via 50 may comprise the same material as a chip wiring metal, such as Cu, Al or an Al alloy (e.g., AlCu, which may contain 0.5-4.0 wt. % Cu, AlTi which may contain up to 25 at. % Ti, or AlTiSi which may contain up to 2 wt. % Ti and up to 1 wt. % Si), W, Ti, Ta, Co, or the like. Materials such as Al, Cu or W may be deposited onto thin underlying layers of an adhesive conductor, such as Ti or Ta, an optional barrier layer thereon, such as TiN, TaN, HfN, TiSiN or TaSiN, and in the case of an electroplated material such as Cu, a nucleation layer thereon, such as sputtered Cu, Ru, Hf, etc. elemental metals such as Al, Cu, Ti, Ta, Hf and the like may be deposited by sputtering or evaporation, whereas compound materials such as TiN, TaN, HfN, TiSiN or TaSiN may be deposited by sputtering, CVD or atomic layer deposition (ALD).

Next, the second metal layer 40 to be electrically connected to the metal via pattern 56 is formed on the insulating layer 30. The second metal layer 40 generally comprises Al or an Al alloy (as described herein), formed as described herein on an adhesive layer and a barrier layer as described herein. Thereby, the second metal layer 40 may be electrically connected to the first metal layer 20 by the metal via pattern 30.

Alternatively, the above-described first and second metal layers 20 and 40 may be copper-based conductive material. The copper-based conductive material may denote pure copper, or copper containing inevitable impurities. Alternatively, the copper-based conductive material may be a copper alloy containing a small quantity of tantalum, indium, tin, zinc, manganese, chromium, titanium, germanium, strontium, platinum, magnesium, aluminum, and/or zirconium.

For example, a damascene process may be used to form the first and second metal layers 20 and 40.

Next, the passivation layer 60 is formed on the second metal layer 40 by photolithography and etching processes, to form the pad window 62.

As apparent from the above description, in a wiring structure, a semiconductor device having the wiring structure, and a method for manufacturing the semiconductor device according to the present invention, a metal via pattern in the form of a cross is formed below a bonding pad (i.e., an uppermost metal layer of the semiconductor device), so as to endure, reduce and or more evenly distribute stress applied to the bond pad region during wire bonding. Provision of the metal via pattern may minimize chip defects.

Further, by providing the metal via pattern in the form of a cross rather than in a mesh form, metal vias may be densely formed in vertical and horizontal directions. This may further effectively prevent propagation of stress as a result of the bonding force, thus reducing or preventing generation of cracks in an insulating layer.

Furthermore, at least a part of an integrated circuit located below the wiring structure (e.g., a circuit under pad [CUP]) may be formed. This allows effective use of the area of the semiconductor chip occupied by the bond pad, thereby reducing the chip size and consequently, chip manufacturing costs, or increasing chip functionality by enabling more chip are to be used for active circuitry.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A wiring structure comprising:
a first metal layer;
an insulating layer on the first metal layer;
a metal via pattern in the insulating layer, electrically connected to the first metal layer,
wherein the metal via pattern includes a plurality of metal vias spaced apart from one another, and each of the metal vias includes a vertical via line extending in a vertical direction and a horizontal via line extending in a horizontal direction crossing the vertical via line; and
a second metal layer on the insulating layer and the metal via pattern.

2. The wiring structure according to claim 1, wherein the vertical via line and horizontal via line have the same thickness.

3. The wiring structure according to claim 2, wherein the thickness is in a range of 0.1 μm to 50 μm.

4. The wiring structure according to claim 1, wherein the vertical via line and horizontal via line have the same length.

5. The wiring structure according to claim 4, wherein the length is in a range of 0.3 μm to 250 μm.

6. The wiring structure according to claim 2, wherein a vertical distance and a horizontal distance between adjacent vertical lines and adjacent horizontal lines in the metal vias are equal to each other.

7. The wiring structure according to claim 6, wherein the horizontal distance is 1.1 to 3 times the thickness.

8. The wiring structure according to claim 1, wherein the metal via pattern occupies a range of 1% to 80% of a total area of the insulating layer between the first and second metal layers.

9. The wiring structure according to claim 1, wherein the vertical via line, the vertical direction, the horizontal via line and the horizontal direction are in first and second planes parallel with an integrated circuit substrate under the first metal layer, and the horizontal direction is at a right angle to the vertical direction.

10. A semiconductor device comprising:
an integrated circuit substrate;
a first metal layer on the integrated circuit substrate;
an insulating layer on the first metal layer;
a metal via pattern in the insulating layer, electrically connected to the first metal layer, wherein the metal via pattern includes a plurality of metal vias spaced apart from one another, and each of the metal vias includes a vertical via line extending in a vertical direction and a horizontal via line extending in a horizontal direction crossing the vertical via line; and
a second metal layer on the insulating layer and the metal via pattern.

11. The semiconductor device according to claim 10, further comprising:
an integrated circuit in or on the integrated circuit substrate.

12. A method for manufacturing a semiconductor device comprising:
preparing an integrated circuit substrate;
forming a first metal layer on the integrated circuit substrate;
forming an insulating layer on the first metal layer; and
forming a metal via pattern in the insulating layer, the metal via pattern being electrically connected to the first metal layer, wherein the metal via pattern includes a plurality of metal vias spaced apart from one another, and each of the metal vias includes a vertical via line extending in a vertical direction and a horizontal via line extending in a horizontal direction crossing the vertical via line.

13. The method according to claim 12, wherein the vertical via line and horizontal via line have the same thickness.

14. The method according to claim 12, wherein the vertical via line and horizontal via line have the same length.

15. The method according to claim 12, wherein a vertical distance and a horizontal distance between adjacent vertical lines and adjacent horizontal lines in the metal vias are equal to each other.

16. The method according to claim 12, further comprising:
forming a second metal layer on the insulating layer, the second metal layer being electrically connected to the metal via pattern.
